(19) United States
(12) Patent Application Publication
(10) Pub. No.: US 2013/0133716 A1
(43) Pub. Date: May 30, 2013

(54) CONNECTION DEVICE FOR CONNECTING AN ELECTRIC COMPONENT INTO A CURRENT PATH

(71) Applicant: Woehner GmbH & Co. KG Elektrotechnische Syst, Roedental (DE)

(72) Inventor: Alex Buettner, Roedental (DE)

(73) Assignee: WOEHNER GMBH & CO. KG ELEKTROTECHNISCHE SYSTEME, Roedental (DE)

(21) Appl. No.: 13/690,414

(22) Filed: Nov. 30, 2012

(30) Foreign Application Priority Data
Nov. 30, 2011 (DE) 102011087492.5

(51) Int. Cl. H01R 25/14; H01L 31/05

(52) U.S. Cl. CPC H01R 25/142; H01L 31/05
USPC 136/244; 439/207

(57) ABSTRACT

A connection device is provided for connecting an electric component into a current path. The connection device comprises a housing having a locking means for locking the housing onto a busbar, a pivotable holding means, into which the electric component can be inserted and connected into the current path by pivoting the holding means; and a terminal clamp, which is connected directly, via the electric component which is connected into the current path, to at least one spring contact, which is provided in the housing and contacts the busbar when the housing is locked on.

The invention relates to a connection device for connecting an electric component into a current path and in particular to a connection device for connecting a cutout for a photovoltaic module string in a photovoltaic installation.

It is necessary to connect components into a current path in many applications. For example, it is necessary to protect a current path against excessively high electric currents by connecting into the current path a fuse which melts, and thus interrupts the current path, if an electric overcurrent occurs. High electric currents can place electric installations at risk and cause fires. Therefore, a fuse for example is incorporated into the circuit as an overcurrent protection means. The fuse may for example comprise a conductor having a small cross-section in a fireproof housing, the conductor or fuse element melting if an electric overcurrent occurs. The fuse link of the fuse consists of an insulating housing, for example made of glass or porcelain, into which the fuse element is incorporated. After the fuse has been activated, it should be changed. Not only in this application, but also in many other applications, it is necessary to connect electronic or electric components into a current path, the electric components having to be changed in a simple manner. Fuse holders for cylindrical fuses are known which are provided in incoming and outgoing lines of a circuit which is to be protected. Fuse holders of this type are conventionally locked onto standard mounting rails and are usually wired to incoming and outgoing lines by means of what are known as box terminals. For example, in a conventional photovoltaic installation, photovoltaic module strings which consist of a plurality of photovoltaic modules connected in series are protected by means of a conventional fuse holder of this type, and the total current of the various photovoltaic module strings is supplied to an inverter, which converts a direct current DC flowing through the busbars into an alternating current AC. A conventional photovoltaic installation of this type can comprise a plurality of photovoltaic module strings and a corresponding number of fuse holders.

The conventional connection devices for connecting an electric component, in particular a fuse, have the drawback that they have to be wired by a technician by means of box terminals. For this purpose, the technician has to wire the connection device to a connection line for example by means of a screwdriver. This assembly process is tedious and time-consuming for the technician, especially if there are a large number of connection lines to be wired. Moreover, manual assembly of this type is susceptible to errors.

It is therefore an object of the present invention to provide a connection device for connecting an electric component into a current path, the assembly thereof being particularly simple and error-proof.

This object is achieved according to the invention by a connection device having the features specified in claim 1.

The invention accordingly provides a connection device for connecting an electric component into a current path, the connection device comprising a housing having a locking means for locking the housing onto a busbar; a pivotable holding means, into which the electric component can be inserted and connected into the current path by pivoting the holding means; and a terminal clamp, which is connected directly, via the electric component which is connected into the current path, to at least one spring contact, which is provided in the housing and contacts the busbar when the housing is locked on.

In one possible embodiment of the connection device according to the invention, a spring presses the spring contact against the busbar when the housing is locked on.

In one possible embodiment of the connection device according to the invention, the spring is a leaf spring.

In one possible embodiment of the connection device according to the invention, the spring contact is L-shaped.

In one possible alternative embodiment of the connection device according to the invention, the spring contact is U-shaped.

In a further possible embodiment of the connection device according to the invention, the terminal clamp is a terminal box.

In an alternative embodiment of the connection device according to the invention, the terminal clamp is a spring-type terminal.

In one possible embodiment of the connection device according to the invention, the electric component is a fuse.

In a further possible embodiment of the connection device according to the invention, the locking means comprises at least one tongue which is formed integrally on the housing of the connection device via at least two ribs, which extend substantially parallel.

In a further possible embodiment of the connection device according to the invention, the spring contact contacts a side portion of the busbar when the housing is locked on.

In an alternative embodiment of the connection device according to the invention, the spring contact contacts an upper face of the busbar when the housing is locked on.

In a further possible embodiment of the connection device according to the invention, the spring contact consists of a resilient conductive material.

In a further possible embodiment of the connection device according to the invention, a photovoltaic module string of photovoltaic modules, which are connected in series and generate a direct electric current when irradiated with light, is connected to the terminal clamp of the connection device.

In one possible embodiment of the connection device according to the invention, the busbar forms a total current node for a plurality of photovoltaic module strings, which are each connected to the busbar via a connection device, in such a way that the direct currents generated by the photovoltaic module strings are added up on the busbar to form a total current.

In a further possible embodiment of the connection device according to the invention, the busbar is connected to an inverter, which converts a total direct current flowing through the busbar into an alternating current In a further possible embodiment of the connection device according to the invention, the busbar is connected to an overvoltage protector.

The invention further provides a photovoltaic installation comprising a plurality of photovoltaic module strings, which each comprise photovoltaic modules, which are connected in series and generate a direct electric current when irradiated with light, each photovoltaic module string being connected to a terminal clamp of an associated connection device, which comprises a housing having a locking means for locking the housing onto a busbar of the photovoltaic installation; a pivotable holding means, into which the electric component can be inserted and connected into the current path by pivoting the holding means; wherein the terminal clamp is connected directly, via the electric component which is connected into the current path, to at least one spring contact, which is provided in the housing and contacts the busbar when the housing is locked on.

In one possible embodiment of the photovoltaic installation according to the invention, said installation comprises a plurality of connection devices for connecting an electric component into one or more current paths, the electric components being cutouts, in particular fuses.

In a further possible embodiment of the photovoltaic installation according to the invention, the busbar is connected to an inverter, which converts a total direct current flowing through the busbar, which forms the total of all of the direct currents generated by the photovoltaic module strings, into an alternating current.

In the following, possible embodiments of the device according to the invention for connecting an electric component into a current path of a photovoltaic installation according to the invention, which uses connection devices of this type, are described in greater detail with reference to the appended drawings, in which:

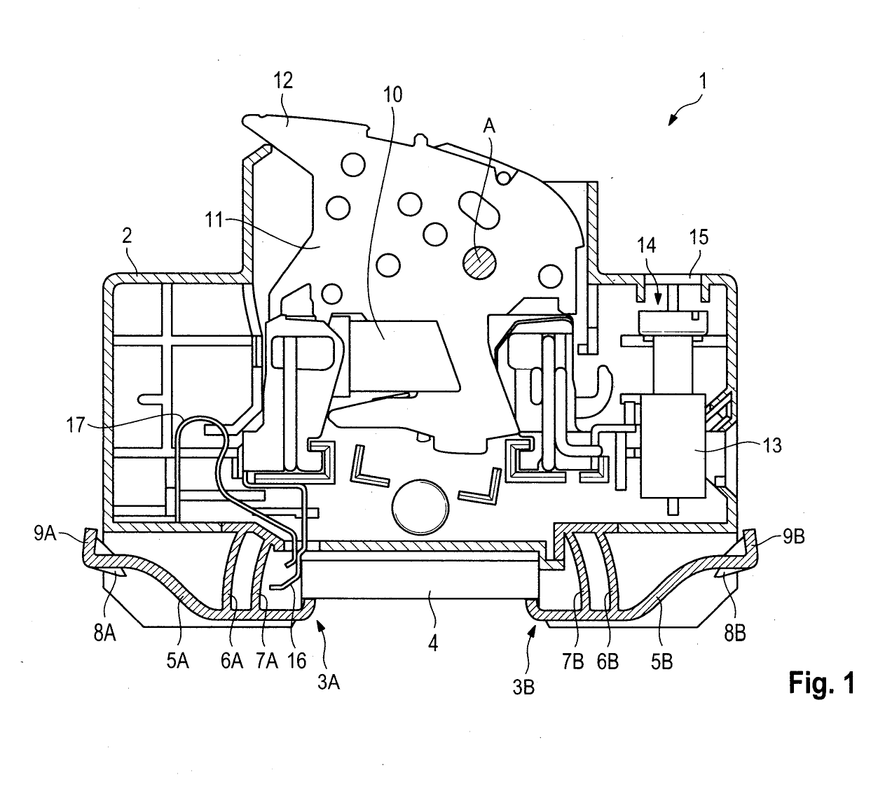

FIG. 1 is a cross-sectional view of an embodiment of a connection device according to the invention for connecting an electronic component into a current path;

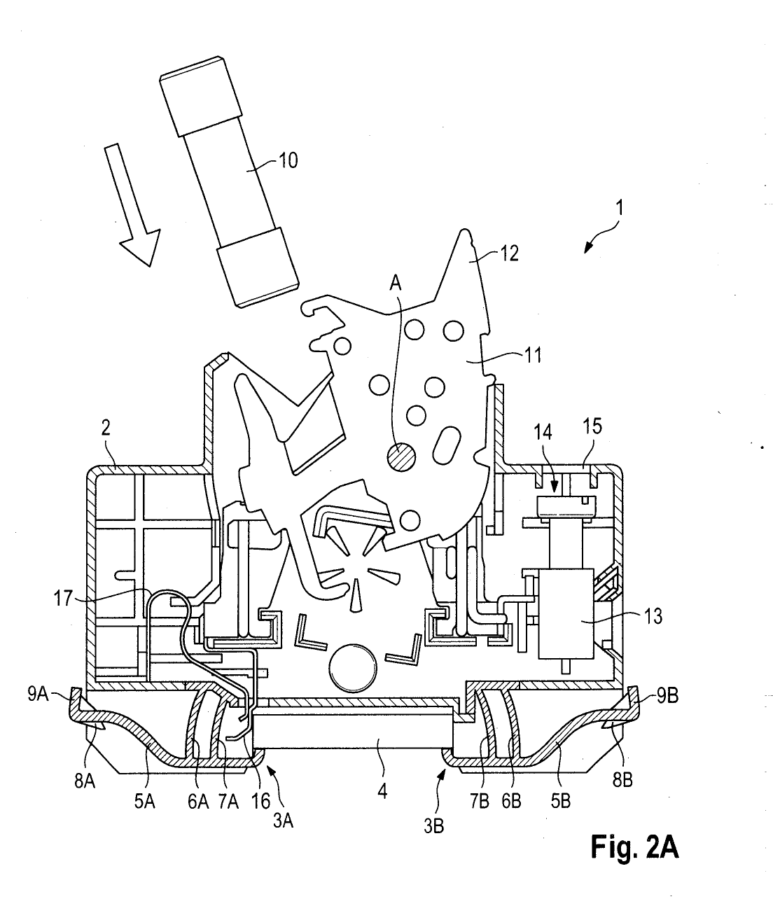

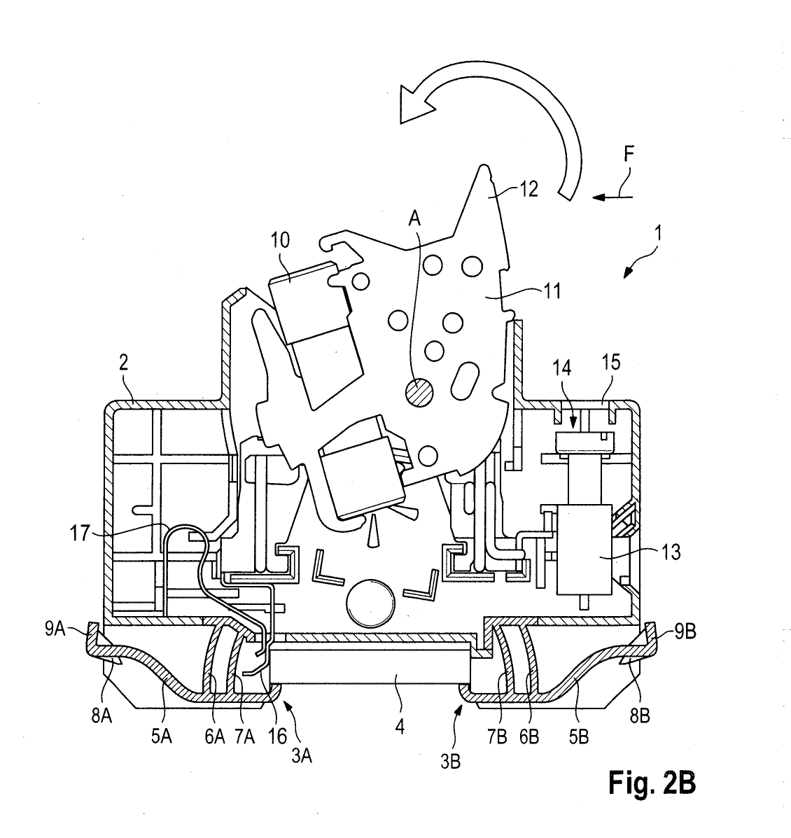

FIG. 2A, 2B are views illustrating how an electronic component is changed with the connection device shown in FIG. 1;

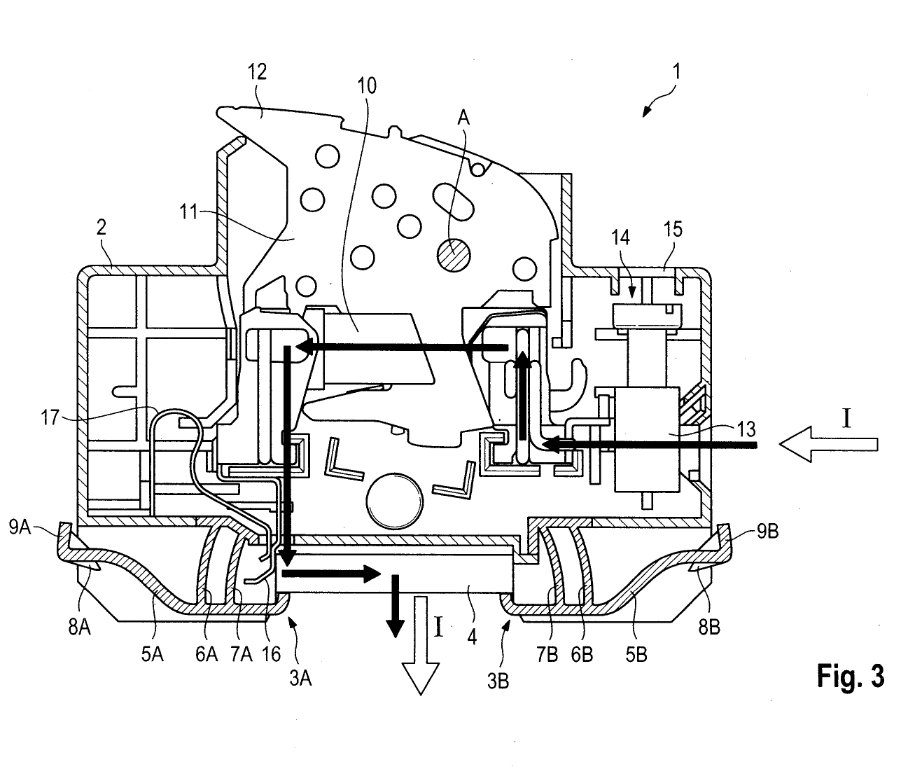

FIG. 3 is a cross-sectional view through the connection device shown in FIG. 1, to illustrate a flow of current through the connection device;

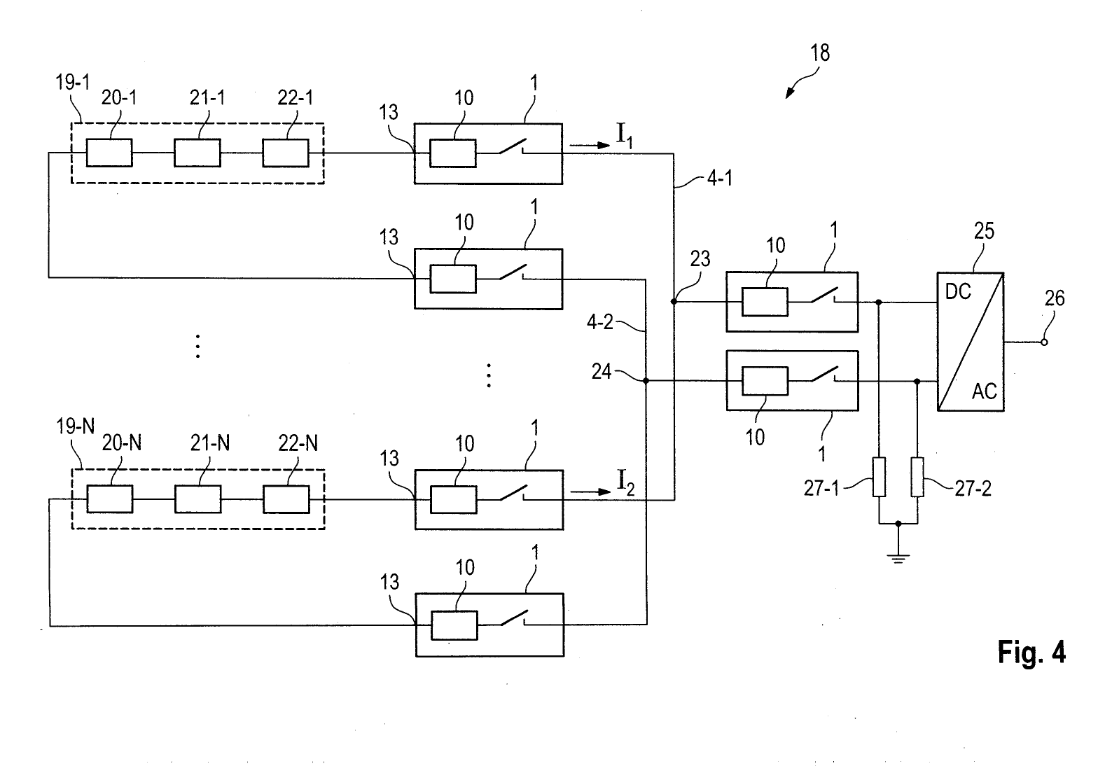

FIG. 4 is a block diagram of an embodiment of a photovoltaic installation according to the invention, which uses connection devices according to the invention;

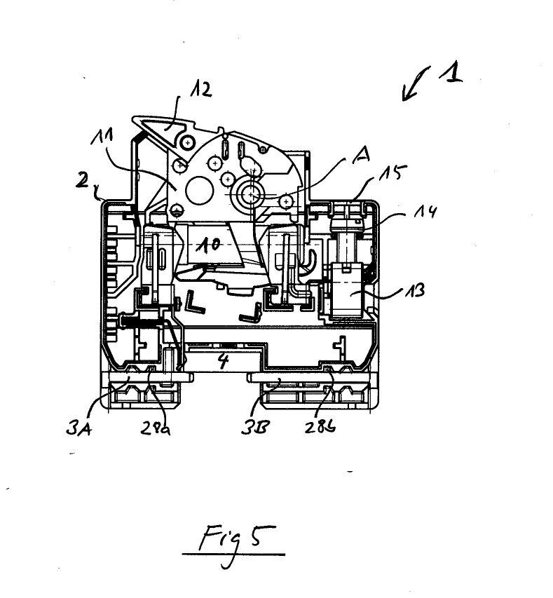

FIGS. 5 to 8 are sectional views through various embodiments of a connection device according to the invention for connecting an electric component into a current path;

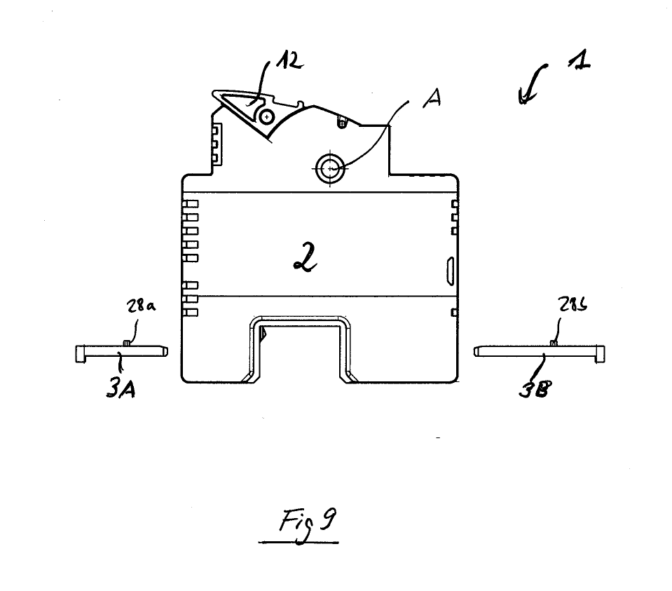

FIG. 9 is a side view with the locking means removed, to illustrate the mode of operation of the embodiments shown in FIGS. 5 to 8;

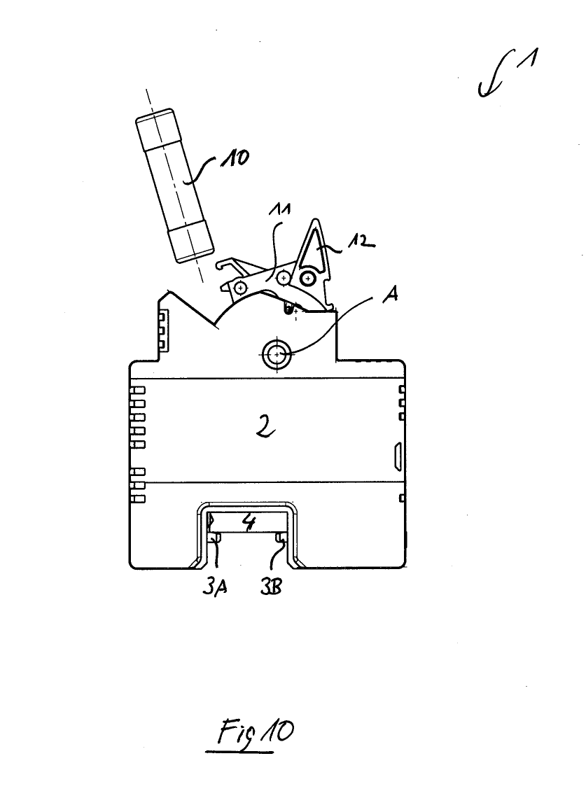

FIG. 10 is a side view illustrating the insertion of a component into the connection device according to the invention for connecting an electric component into a current path.

As can be seen in the cross-sectional view according to FIG. 1, the connection device 1 comprises a housing 2 in the embodiment shown. FIG. 1 shows a housing wall of the housing 2. On the underside of the housing 2, as shown in FIG. 1, there is at least one locking means 3 for locking the housing 2 onto a busbar 4. Each of the two locking means 3A, 3B shown in FIG. 1 comprises a tongue 5A, 5B, which in each case is integrally formed on the housing 2 of the connection device 1 via at least two ribs 6A, 6B; 7A, 7B, which extend substantially parallel. Further, the locking means 3A, 3B may comprise a locking portion 8A, 8B and an actuation portion 9A, 9B in each case. The busbar 4 consists of a conductive material for conducting current, the busbar 4 simultaneously serving as a mounting rail for holding or securing the connection device 1. The locking means 3A, 3B, comprising the ribs 6A, 6B, 7A, 7B and the tongue 5A, 5B, may consist of a flexible material having resilient properties. As is shown in FIG. 1, the tongue 5A, 5B is for example bent in an S shape. In one possible embodiment, the housing 2 shown in FIG. 1 can be composed of two housing half-shells. In this case, in one possible embodiment, the ribs 6A, 6B, 7A, 7B and the tongues 5A, 5B of the locking means 3A, 3B are formed integrally on one of the two housing half-shells. The distance between the two locking means 3A, 3B, as shown in FIG. 1, corresponds to the width of the busbar 4, the tips of the tongues 5A, 5B each engaging around the busbar 4 in the locked state according to FIG. 4, in such a way that the connection device 1 according to the invention is positioned securely on the busbar 4 when locked in or locked on. A locking portion 8A, 8B is provided on the actuation portion 9A, 9B in each case. The end of the respective tongue 5A, 5B opposite the actuation portion 9A, 9B is drawn upwards in a hook shape, and serves as a locking portion for locking the connection device 1 onto the mounting rail or busbar 4 shown in FIG. 1.

To unlock or release the housing 2 from the busbar 4, the locking means 3A, 3B is moved outwards. This is possible because the locking means 3A, 3B are connected resiliently to the housing 2 of the connection device 1 via the ribs 6A, 6B, 7A, 7B. The embodiment shown in FIG. 1 comprises two locking means 3A, 3B. Alternatively, the connection device 1 may also comprise only one locking means 3, for example the locking means 3A.

The connection device 1 shown in FIG. 1 is used for connecting an electric component 10, which may for example be an electronic cut-out or the like. The connection device 1 is further provided with a pivotable holding means or a fuse holder 11, which can be actuated by hand. The electric component or the cutout 10 is inserted into the pivotable holding means 11 and connected into a current path by pivoting the holding means 11. This is clearly shown in FIG. 2A, 2B.

As can be seen in FIG. 2A, the pivotable holding means 11 is used for receiving an electric component 10. In the embodiment shown, the electric component 10 is a cutout, in particular a fuse. Alternatively, the electric component 10 may also be another electric component, for example an insertable resistor, an insertable capacitor or an insertable inductor. After the electric or electronic component 10 has been inserted into the pivotable holding means 11, the holding means 11 can be brought from the position shown in FIG. 2A, 2B to the position according to FIG. 1 by actuating said means. For this purpose, as shown in FIG. 2B, a force F is exerted on an actuation portion 12 of the holding means 11. By pivoting the holding means 11, the electric component 10 is connected into a current path, as is illustrated in FIG. 3.

The connection device 1 shown in FIG. 1 comprises a terminal clamp 13. In the embodiment shown in FIG. 1, the terminal clamp 13 is a terminal box, by means of which a connection cable or a connection wire can be connected to the connection device 1 using a clamp screw 14. By means of a tool, in particular a screwdriver, the clamp screw 14 can be actuated via an opening 15 which is provided in the housing 2 of the connection device 1. As is shown in FIG. 1, the head of the clamp screw 14 is located inside the housing 2, in such a way that an individual cannot touch it. Alternatively, the terminal clamp 13 may also be in the form of a spring-type terminal, into which a connection wire can lock. The terminal clamp 13 is connected directly, via the component 10 which is connected into the current path, to at least one spring contact 16, which is provided in the housing 2 and contacts the busbar 4 directly when the housing 2 is locked on as shown in FIG. 1. In this context, the spring contact 16 is pressed against the busbar 4 so as to produce an electric contact. The spring contact 16 also consists of a conductive material. In the embodiment shown in FIG. 1, the connection device 1 is further provided with at least one spring 17, which presses the spring contact 16 mechanically against the busbar 4 when the connection device 1 is locked in or locked on. The spring 17 may be a leaf spring, as shown in FIG. 1. Alternatively, the spring 17 may also be a spring of a different type, for example a scroll spring or the like. By means of the spring 17, the spring contact 16 is pressed against the upper face of the busbar 4 with a predetermined force. The tip of the spring contact 16 is substantially L-shaped, as shown in FIG. 1. Alternatively, the end portion of the spring contact 16 may also be U-shaped and contact the innermost rib 7A, 7B of the locking means 3A, 3B. In the embodiment shown in FIG. 1, the spring contact 16 is pressed against the left side portion of the busbar 4. Alternatively, it is also possible for two spring contacts 16 to be pressed against the two side portions of the busbar 4 and to be connected to the terminal clamp 13 in a parallel manner via the electric component 10. In a further possible embodiment, the spring contact 16 is pressed against the upper face of the busbar 4 when locked on. The spring contact 16 is connected to an internal contact 17, which is used for contacting the inserted electric component 10, via an internal current line. The inserted electric component 10 leads a current path from the terminal clamp 13 through the inserted component 10, the contact 17 and the spring contact 16 to the busbar 4, as is shown in FIG. 3.

If the electric component 10 is a cutout, a current which is fed in is fed directly via the inserted cutout 10, by means of the connection device 1 according to the invention, to the busbar 4, from which it can be led for example centrally to an inverter. As can be seen in FIG. 1, the connection device 1 according to the invention comprises only one clamping point 13 in the form of a terminal box or a spring-type terminal, which is electrically connected to the busbar 4 via the spring contact 16. The spring contact 16 consists of an electrically conductive material, for example copper, and is of a low ohmic resistance. Further, the spring contact 16 may also be a copper alloy which has resilient properties. The busbar 4 can have a predetermined width and height, for example a height of 5 mm and a width of 30 mm. In one possible embodiment, the distance between the two locking means 3A, 3B, as shown in FIG. 1, corresponds to the width of the busbar 4. The busbar 4 is used for transporting electric current I, and also serves as a mechanical mounting rail for the locked-on connection device 1. No tools are necessary for locking the connection device 1 to the busbar 4. If the terminal clamp 13 is a terminal box 13, a screwdriver for example is actuated by the technician to screw it tight. If the terminal clamp 13 is a spring-type terminal or a push-in terminal, no tool is necessary for connecting an electric cable to the connection device 1. In the embodiment shown in FIG. 1, the connection device 1 is used for connecting an electric component 10 into a current path. In an alternative embodiment, a plurality of electronic components 10 can be connected into one or more current paths simultaneously, in parallel, by actuating the holding means 11. In this context, the pivotable holding means 11 may be formed symmetrically, in such a way that it can only receive a particular type of electronic component 10. This can prevent components from being inserted in the wrong places. The dimensions of the component 10 to be inserted correspond to the size of the geometric recess of the pivotable holding means 11.

If an overcurrent occurs, an inserted fuse 10 can melt for example, in such a way that the ohmic resistance in the current path becomes very high and interrupts the flow of current. The burnt-out fuse is then changed once the pivotable holding means 11 has been rotated clockwise about the axis A. In one possible embodiment, the connection device 1 comprises a display means, which displays that the fuse 10 has melted and thus informs a technician that the fuse 10 needs to be changed.

FIG. 4 is a block diagram of a photovoltaic installation 18 according to the invention, which uses connection devices 1 for connecting electronic components 10. The photovoltaic installation 18 comprises a plurality of photovoltaic module strings 19-1, 19-2, 19-n, which each comprise a plurality of photovoltaic modules 20, 21, 22 connected in series. In the embodiment shown in FIG. 4, each photovoltaic module string 19-i comprises three connected photovoltaic modules 20, 21, 22 respectively. The number of photovoltaic modules connected in series can vary; for example, a plurality of photovoltaic modules 20, 21, 22 may also be connected in series in a photovoltaic module string 19-i. The photovoltaic modules generate a direct electric current DC when irradiated with light, in particular sunlight. As is shown in FIG. 4, each photovoltaic module 19-i is connected via connection devices 1 to two nodes 23, 24, which serve as total current nodes. Via the connection devices 1, electric components 10 can be connected into the current path by hand in each case. Alternatively, the connection devices 1 may also be connected in an electronically controlled manner. The photovoltaic module strings 19-i are connected to terminal clamps 13 of the connection devices 1. The connection devices 1 are positioned on busbars 4-1, 4-2, which conductively connect the photovoltaic modules 9-1 to the nodes 23, 24 after the electric components 10 have been inserted and connected into the current path. The nodes 23, 24 form total current nodes. As is shown in FIG. 4, a total current I-1+I-2 is formed at the node 23, and flows via a main cutout 10 to an inverter 25, which converts the total current, which is in the form of a direct current DC, into an alternating current AC. The generated alternating current AC is fed into a power supply network via a terminal 26. The busbars 4-1, 4-2 can be connected to the overvoltage protection means 27-1, 27-2 via the main cutouts, as is shown in FIG. 4. As can be seen in FIG. 4, a plurality of connection devices 1 can be locked onto the busbars 4-1, 4-2 in a simple manner, without a technician having to resort to a tool or the like in order to carry out the assembly. This greatly reduces the total work involved in assembling the photovoltaic installation 18. Moreover, it is ensured that there are no contact problems or incorrect contacts resulting from assembly errors, and that all of the photovoltaic modules 19-1 supply the direct current which they generate to the invertor 25. In the embodiment shown in FIG. 4, two cutouts 10 are connected to each photovoltaic module string 19-i, so as to protect the lines or the photovoltaic modules from damage resulting from an overcurrent. The cutouts 10 also insulate a damaged photovoltaic module string, in particular if a short circuit has occurred therein, in such a way that the remaining photovoltaic installations 18 can continue to generate electric current unimpaired. In the photovoltaic installation 18 shown in FIG. 4, a plurality of connection devices 1 and a corresponding number of photovoltaic module strings 19-i can be provided. FIG. 4 shows a possible example application for a connection device 1 according to the invention, in a photovoltaic installation 18 according to the invention. The connection device 1 according to the invention is not limited to this application, but can be used widely in various installations in which electric or electronic components 10 are to be connected into a current path. The electric components 10 are not limited to cutout components, but may also comprise other electric or electronic components, for example resistors, capacitors or coils. The connection device 1 according to the invention preferably comprises a holding means 11 which can be actuated and pivoted by hand, as is shown in FIG. 1. Alternatively, the holding means 11 may also be actuated in an electronically controlled manner. Moreover, when a current path has been closed successfully by means of an electric component 10, this can further be displayed by a display means and/or reported to a control means via a line. In one possible embodiment, when a fuse 10 melts or an inserted component 10 is destroyed, this can also be electronically reported or displayed to a technician.

FIG. 5 shows a further embodiment for a possible implementation of a connection device for connecting an electronic component into a current path according to the invention.

In the embodiment shown in FIG. 5, the locking means 3 is formed by two removable slide locks 3A, 3B. These two slide locks 3A, 3B are inserted at the underside of the housing 2 and can be displaced laterally in such a way that they engage with the busbar 4 from below and thus lock the housing 2 onto the busbar 4. The busbar 4 shown in FIG. 5 has a small bar cross-section, for example 20×5 mm. The length of the locking elements 3A, 3B depends on the width of the busbar 4. If the busbar 4 is relatively narrow, as in the embodiment shown in FIG. 5, and has a width of just 20 mm for example, longer locking elements are inserted into the housing 2 of the connection device 1 for attaching onto the busbar 4, and are subsequently displaced horizontally towards the centre of the busbar 4 for locking securely onto the busbar 4. The two tips of the locking elements 3A, 3B engage with the busbar 4 from below, as is shown in FIG. 5. The heads of the locking elements, at the other end of each of the locking elements 3A, 3B, preferably lock positively in openings which are provided for this purpose in the housing 2 of the connection device 1.

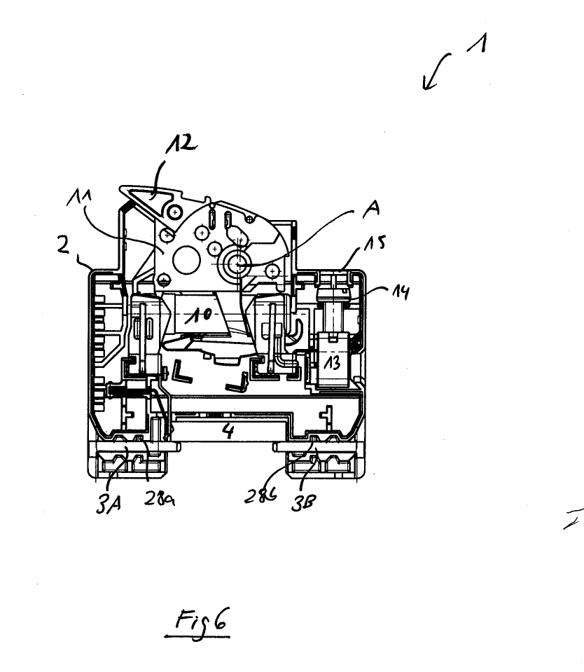

FIG. 6 shows a further embodiment of a connection device 1, which is locked onto a wider busbar 4. In the embodiment shown in FIG. 6, the busbar 4 has a cross-sectional area of 30×5 mm, for example. As in the embodiment shown in FIG. 5, the locking means 3 comprises two slide locks 3A, 3B, which are each inserted into an opening of the housing 2 and are subsequently displaced laterally in such a way that the tips thereof engage with the busbar 4 from below, as is shown in FIG. 6. As is shown in FIG. 6, because of the greater width of the busbar, the length of the second locking element 3B can be made shorter than in the embodiment shown in FIG. 5. In a preferred implementation, the two opposing locking elements or slide locks 3A, 3B are of the same length, in such a way that they are interchangeable, and assembly is thus simplified.

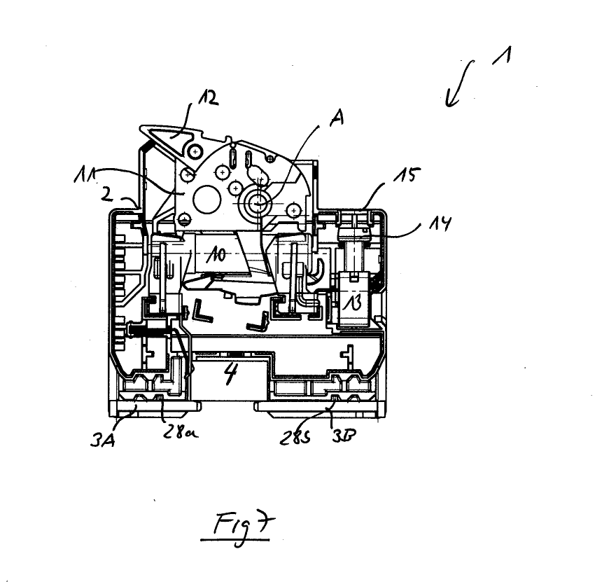

FIG. 7 shows a further embodiment of a connection device 1 for connecting an electronic component into a current path. In the embodiment shown in FIG. 7, the connection device 1 is locked onto a thicker busbar 4. In the embodiment shown in FIG. 7, the busbar 4 has a width of 20 mm and a height or thickness of 10 mm, for example. The housing 2 of the connection device 1 is formed in such a way that it can be placed on a busbar of such a width. In the embodiment shown in FIG. 7, the locking means 3 is also formed by two locking elements or slide locks 3A, 3B, which are inserted into the housing 2 of the connection device 1 and are subsequently displaced laterally with respect to another, in such a way that they engage with the busbar 4 from below. Similarly to the embodiment shown in FIG. 5, the two slide locks 3A, 3B comprise a relatively short front slide lock 3A and a relatively long rear slide lock 3B. In an alternative implementation, the two slide locks 3A, 3B may also be of the same length.

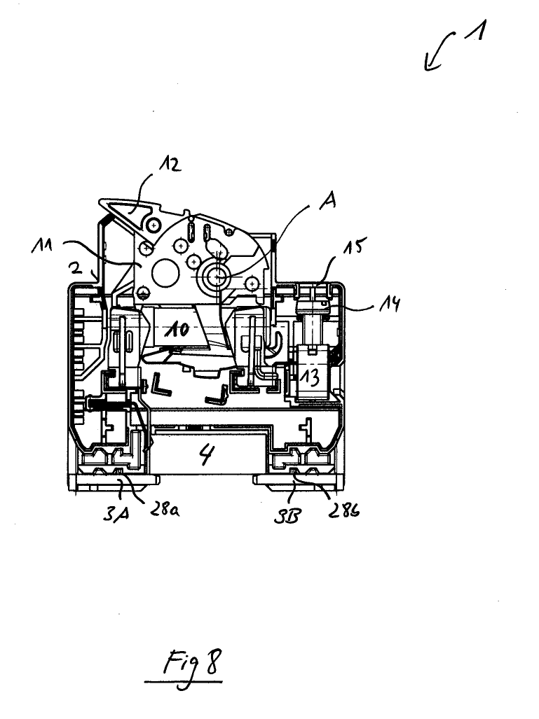

FIG. 8 shows a further embodiment of a connection device 1 according to the invention, which is locked onto a busbar 4. In the embodiment shown in FIG. 8, the busbar 4 has a larger internal cross-section of 30×10 mm, for example. The locking means is also formed by two locking elements or slide locks 3A, 3B, which engage with the busbar 4 from below by locking, as is shown in FIG. 8.

FIG. 9 is a side view of a connection device 1 according to the invention, in which the locking means is formed by two slide locks 3A, 3B. As is shown in FIG. 9, the two slide locks 3A, 3B are for example L-shaped and comprise a locking projection 28A, 28B, which can lock into a corresponding recess inside the housing 2 so as to engage with a busbar 4 from below. The manner in which the locking projections 28A, 28B lock into a corresponding recess of the housing 2 is also shown in the side views of FIG. 5 to FIG. 8.

An installer or technician has the option of changing the route of a rail by levering the locking elements or slide locks 3A, 3B out of the housing 2 of the connection device 1 and pushing them back in into another route position, as is shown schematically in FIG. 9.

FIG. 10 is a further side view of the connection device 1 according to the invention, in which the pivotable holding means 11 is pivoted out of the housing 2 of the connection device 1 about the axis A, in such a way that a component 10, in particular an electric cutout, can be inserted into the holding means 11 by a user. In the embodiment shown in FIG. 10, the connection device 1 is locked onto the busbar 4 by means of two slide locks 3A, 3B, which are inserted into the housing 2. FIG. 10 shows the tips or front portions of the two slide locks 3A, 3B, which engage with the busbar 4 from below. To release the connection device 1 from the busbar 4, a technician or installer may for example exert mechanical pressure on the two tips by means of a tool, in such a way that the two slide locks 3A, 3B move apart laterally and no longer engage with the busbar 4 from below. Subsequently, the connection device 1 can be removed from the busbar 4. In one possible embodiment, the housing 2 of the connection device 1 comprises two superimposed introduction openings for locking elements on the two sides of the busbar 4, so as to make it possible to lock in on busbars 4 of different thickness or height. In this way, it is possible to lock the connection device 1 flexibly either onto a busbar 4 having a smaller height of for example 5 mm or onto a busbar 4 having a greater thickness of for example 10 mm.

### LIST OF REFERENCE NUMERALS

1 connection device
2 housing
3A, 3B locking means
4 busbar
5A, 5B tongue
6A, 6B, 7A, 7B ribs
8A, 8B locking portion
9A, 9B actuation portion
10 component
11 fuse holder/holding means
12 actuation portion
13 terminal clamp
14 clamp screw
15 opening
16 spring contact
17 spring
18 photovoltaic installation
19 photovoltaic module string
20, 21, 22 photovoltaic modules
23, 24 total nodes
25 inverter
26 network connection
27 overvoltage protection means
28 locking projections

I claim:

1. A connection device for connecting an electric component into a current path, the connection device comprising:
a housing having a locking means for locking the housing onto a busbar;
a pivotable holding means, into which the electric component can be inserted and connected into the current path by pivoting the holding means; and
a terminal clamp, which is connected directly, via the electric component which is connected into the current path, to at least one spring contact, which is provided in the housing and contacts the busbar when the housing is locked on.

2. The connection device according to claim 1, further comprising a spring pressing the spring contact against the busbar when the housing of the connection device is locked on.

3. The connection device according to claim 2, wherein the spring is a leaf spring.

4. The connection device according to claim 1, wherein the spring contact is L-shaped or U-shaped.

5. The connection device according to claim 1, wherein the terminal clamp is a terminal box or a spring-type terminal.

6. The connection device according to claim 1, wherein the electric component is a fuse.

7. The connection device according to claim 1, wherein the locking means comprises at least one tongue which is formed integrally on the housing of the connection device via at least two ribs, which extend substantially parallel.

8. The connection device according to claim 1, wherein the spring contact contacts a side portion or an upper face of the busbar when the housing is locked on.

9. The connection device according to claim 1, wherein the spring contact consists of a resilient conductive material.

10. The connection device according to claim 1, further comprising a photovoltaic module string of photovoltaic modules, which are connected in series and generate a direct electric current when irradiated with light, is connected to the terminal clamp.

11. The connection device according to claim 10, wherein the busbar forms a total current node for a plurality of photovoltaic module strings, which are each connected to the busbar via a connection device, in such a way that the direct currents generated by the photovoltaic module strings are added up on the busbar to form a total current.

12. The connection device according to claim 1, wherein the busbar is connected to an inverter, which converts a total direct current flowing through the busbar into an alternating current.

13. The connection device according to claim 1, wherein the busbar is connected to an overvoltage protector.

14. A photovoltaic installation comprising:
a connection device for connecting an electric component into a current path, the connection device comprising
a housing having a locking means for locking the housing onto a busbar,
a pivotable holding means, into which the electric component can be inserted and connected into the current path by pivoting the holding means, and
a terminal clamp, which is connected directly, via the electric component which is connected into the current path, to at least one spring contact, which is provided in the housing and contacts the busbar when the housing is locked on; and
a plurality of photovoltaic module strings, which each comprise photovoltaic modules, which are connected in series and generate a direct electric current when irradiated with light, each photovoltaic module string being connected to the terminal clamp of an associated connection device.

15. The photovoltaic installation according claim 14, further comprising an inverter, wherein the busbar is connected to an inverter, which converts a total direct current flowing through the busbar, which forms the total of all of the direct currents generated by the photovoltaic module strings, into an alternating current.
